(19) United States
(12) Patent Application Publication
(10) Pub. No.: US 2025/0199045 A1
(43) Pub. Date: Jun. 19, 2025

(54) MEASUREMENT CHAMBER FOR PERFORMING MEASUREMENTS WITH RESPECT TO A DEVICE UNDER TEST, ESPECIALLY UNDER DIFFERENT TEMPERATURES

(71) Applicant: Rohde & Schwarz GmbH & Co. KG, Munich (DE)

(72) Inventor: Constantin SCHWERDTFEGER, Munich (DE)

(21) Appl. No.: 18/541,870

(22) Filed: Dec. 15, 2023

(51) Int. Cl. G01R 29/10

(52) U.S. Cl. CPC G01R 29/105

(57) ABSTRACT

A measurement chamber for performing measurements with respect to a device under test, especially under different temperature conditions, is provided. Said measurement chamber comprises an inlet and/or inlet guide for intake of a fluid, especially a temperature pre-conditioned fluid, into the measurement chamber, an outlet and/or outlet guide for out-take of the fluid from the measurement chamber, and a temperature conditioning element arranged inside the measurement chamber. In this context, the temperature conditioning element is configured to be temperature-effective with respect to the inlet and/or inlet guide according to a first temperature and/or to be temperature-effective with respect to the outlet and/or outlet guide according to a second temperature.

### TECHNICAL FIELD

The disclosure relates to performing measurements with respect to a device under test, especially under different temperature conditions. In particular, the disclosure relates to a measurement chamber for performing measurements with respect to a device under test, especially under different temperature conditions, a system comprising such a measurement chamber, and a corresponding measurement method.

### BACKGROUND ART

Generally, in times of an increasing number of applications comprising circuitry being sensitive to temperature, exemplarily communication applications, there is a growing need of a measurement chamber, a system comprising such a measurement chamber, and a corresponding measurement method for performing measurements with respect to such applications in order to verify their correct functioning, especially under different temperature conditions.

Document US 2023/0031149 A1 discloses a test system for testing a device under test. The test system includes an anechoic chamber for encompassing a device under test to be tested by means of radio frequency radiation. The anechoic chamber has a wall with an opening provided in the wall. The test system also has a feedthrough assembly for transporting a fluid into the anechoic chamber or from the anechoic chamber. The feedthrough assembly has a pipe that extends through the opening such that the pipe is fed through the opening. The pipe is routed such that radio frequency radiation is prevented from leaving the anechoic chamber via the pipe. The fluid is conditioned in a defined manner by an environmental conditioning device, which means that the fluid may relate to cold or hot air as well as humid or non-humid air. The environmental conditioning device is arranged outside the anechoic chamber and associated with the corresponding intake feedthrough assembly that forwards the fluid to the anechoic chamber.

Disadvantageously, as the fluid has to travel a relatively long way from the environmental conditioning device to the anechoic chamber, achieving a target temperature at the device under test is inaccurate and inefficient, wherein extreme temperatures are especially not achievable at the device under test without damaging constructive parts, such as seals or bearings, along said way from the environmental conditioning device to the device under test due to their lack of suitability for particularly low or high temperatures.

### SUMMARY

Thus, there is a need to provide a measurement chamber for performing measurements with respect to a device under test, especially under different temperature conditions, a system comprising such a measurement chamber, and a corresponding measurement method, wherein not only a target temperature at the device under test can be achieved in a particularly accurate and efficient manner but also constructive parts, such as seals or bearings, are prevented from being damaged, especially in the context of extreme temperature testing.

This is achieved by the embodiments provided in the enclosed independent claims. Advantageous implementations of the present disclosure are further defined in the dependent claims.

According to a first aspect of the disclosure, a measurement chamber for performing measurements with respect to a device under test, especially under different temperature conditions, is provided. Said measurement chamber comprises an inlet and/or inlet guide for intake of a fluid, especially a temperature pre-conditioned fluid, into the measurement chamber, an outlet and/or outlet guide for out-take of the fluid from the measurement chamber, and a temperature conditioning element arranged inside the measurement chamber. In this context, the temperature conditioning element is configured to be temperature-effective with respect to the inlet and/or inlet guide according to a first temperature and/or to be temperature-effective with respect to the outlet and/or outlet guide according to a second temperature. Advantageously, not only a target temperature at the device under test can be achieved in a particularly accurate and efficient manner but also constructive parts, such as seals or bearings, are prevented from being damaged, especially in the context of extreme temperature testing.

According to an implementation form of the first aspect of the disclosure, the measurement chamber comprises or is an anechoic chamber. Advantageously, for instance, with special respect to over-the-air measurements, accuracy can efficiently be increased.

According to a further implementation form of the first aspect of the disclosure, the first temperature is lower than the second temperature. As an alternative, the first temperature is higher than the second temperature. Advantageously, for example, the measurement chamber can flexibly be used in the context of both cooling and heating scenarios.

According to a further implementation form of the first aspect of the disclosure, the temperature conditioning element comprises a first surface of a first element temperature. In addition to this or as an alternative, the temperature conditioning element comprises a second surface of a second element temperature. Advantageously, for instance, a space-saving design can be achieved.

According to a further implementation form of the first aspect of the disclosure, the first surface is parallel or substantially parallel to the second surface. Advantageously, for example, space requirements can further be reduced.

With respect to the above-mentioned term “substantially parallel”, it is noted that said term may especially be understood as deviation of not more than 15 degrees, preferably not more than 10 degrees, more preferably not more than 5 degrees, most preferably not more than 3 degrees, from corresponding parallelism.

According to a further implementation form of the first aspect of the disclosure, the temperature conditioning element is plate-type. In addition to this or as an alternative, the temperature conditioning element comprises or is a Peltier element. Advantageously, for instance, complexity can be reduced, thereby increasing efficiency, especially cost-efficiency. Further advantageously, the corresponding temperature dynamic can efficiently be improved.

According to a further implementation form of the first aspect of the disclosure, the inlet and/or inlet guide is arranged with respect to the outlet and/or outlet guide in a parallel or substantially parallel manner. Advantageously, for example, space requirements can further be reduced.

With respect to the above-mentioned term “substantially parallel”, it is noted that said term may especially be understood as deviation of not more than 15 degrees, preferably not more than 10 degrees, more preferably not more than 5 degrees, most preferably not more than 3 degrees, from corresponding parallelism.

According to a further implementation form of the first aspect of the disclosure, the temperature conditioning element is arranged between the inlet and/or inlet guide and the outlet and/or outlet guide. Advantageously, for instance, complexity can be reduced, thereby increasing efficiency, especially cost-efficiency.

According to a further implementation form of the first aspect of the disclosure, the inlet and/or inlet guide comprises or is at least one of an inlet hose, an inlet pipe, an inlet corrugated pipe, an inlet bellows-based hose, an inlet bellows-based pipe, or any combination thereof. In addition to this or as an alternative, the outlet and/or outlet guide comprises or is at least one of an outlet hose, an outlet pipe, an outlet corrugated pipe, an outlet bellows-based hose, an outlet bellows-based pipe, or any combination thereof. Advantageously, for example, not only complexity can be reduced but also flexibility can be increased, which leads to an increased efficiency.

According to a further implementation form of the first aspect of the disclosure, the measurement chamber further comprises a thermally isolated space inside the measurement chamber for surrounding the device under test. In this context, the thermally isolated space comprises a first opening for guiding the fluid from the inlet and/or inlet guide into the thermally isolated space. In addition to this or as an alternative, the thermally isolated space comprises a second opening for guiding the fluid out of the thermally isolated space to the outlet and/or outlet guide. Advantageously, for instance, especially in the context of achieving the target temperature at the device under test, not only accuracy but also efficiency can further be increased.

According to a further implementation form of the first aspect of the disclosure, the thermally isolated space is of spherical or ellipsoidal shape. Advantageously, for example, complexity can further be reduced, thereby increasing efficiency, especially cost-efficiency, which can analogously apply for the following implementation form.

According to a further implementation form of the first aspect of the disclosure, the thermally isolated space is a thermally isolated bubble or a kind thereof.

According to a further implementation form of the first aspect of the disclosure, the thermally isolated space is formed by a radio frequency neutral material. In addition to this or as an alternative, the thermally isolated space comprises a radio frequency neutral upper dome. Advantageously, for instance, distorted measurement results can be avoided, thereby ensuring a high accuracy.

According to a further implementation form of the first aspect of the disclosure, the temperature conditioning element is arranged such that the temperature conditioning element is as close as possible to the thermally isolated space or substantially as close as possible to the thermally isolated space. Advantageously, for example, especially in the context of achieving the target temperature at the device under test, not only accuracy but also efficiency can further be increased.

With respect to the above-mentioned term “substantially as close as possible”, it is noted that said term can especially be understood as not as close as possible but advantageous, exemplarily from a construction point of view, with respect to the correspondingly closest arrangement.

According to a further implementation form of the first aspect of the disclosure, the fluid comprises or is at least one of air, nitrogen, sulfur hexafluoride, or any combination thereof. Advantageously, for instance, flexibility can further be increased, thereby increasing efficiency.

According to a further implementation form of the first aspect of the disclosure, the temperature conditioning element is shielded, preferably such that the temperature conditioning element does not create interference, especially electromagnetic interference, within the measurement chamber. Advantageously, for example, accuracy can further be increased.

According to a further implementation form of the first aspect of the disclosure, the measurement chamber further comprises a positioner for positioning the device under test, and/or a controller for controlling the temperature conditioning element and/or the positioner. Advantageously, for instance, flexibility can further be increased, which can analogously apply for the following implementation form.

With respect to the above-mentioned positioner, it is noted that it might be particularly advantageous if the positioner comprises at least a part of the above-mentioned inlet and/or inlet guide and/or outlet and/or outlet guide. Additionally or alternatively, it might be particularly advantageous if the above-mentioned thermally isolated space is arranged on the positioner.

According to a further implementation form of the first aspect of the disclosure, the positioner comprises at least two axis, preferably at least two rotational axis, more preferably at least three axis, most preferably three rotational axis or at least three rotational axis.

According to a second aspect of the disclosure, a system is provided. Said system comprises a measurement chamber according to the first aspect of the disclosure or any of its implementation forms, respectively, and a temperature conditioning device. In this context, the temperature conditioning device is configured to condition a fluid to be fed into the inlet and/or inlet guide of the measurement chamber according to a first device temperature. In addition to this or as an alternative, the temperature conditioning device is configured to condition the fluid taken out from the outlet and/or outlet guide of the measurement chamber according to a second device temperature. Advantageously, not only a target temperature at the device under test can be achieved in a particularly accurate and efficient manner but also constructive parts, such as seals or bearings, are prevented from being damaged, especially in the context of extreme temperature testing.

According to a third aspect of the disclosure, a measurement method is provided. Said measurement method comprises the steps of placing a device under test into a measurement chamber according to the first aspect of the disclosure or any of its implementation forms, respectively, and performing at least one measurement, especially at least one over-the-air measurement, with respect to the device under test, preferably within a temperature range between −40 degrees Celsius and 85 degrees Celsius. Advantageously, not only a target temperature at the device under test can be achieved in a particularly accurate and efficient manner but also constructive parts, such as seals or bearings, are prevented from being damaged, especially in the context of extreme temperature testing.

### BRIEF DESCRIPTION OF THE DRAWINGS

The above-described aspects and implementation forms of the present disclosure will be explained in the following description of specific embodiments in relation to the enclosed drawings, in which:

FIG. 1 shows an exemplary embodiment of the first aspect of the disclosure;

FIG. 2 shows a further exemplary embodiment of the first aspect of the disclosure based on FIG. 1;

FIG. 3 shows an exemplary embodiment of the second aspect of the disclosure based on FIG. 1;

FIG. 4 shows a further exemplary embodiment of the second aspect of the disclosure based on FIG. 2; and

FIG. 5 shows a flow chart of an exemplary embodiment of the third aspect of the disclosure.

### DETAILED DESCRIPTIONS OF EMBODIMENTS

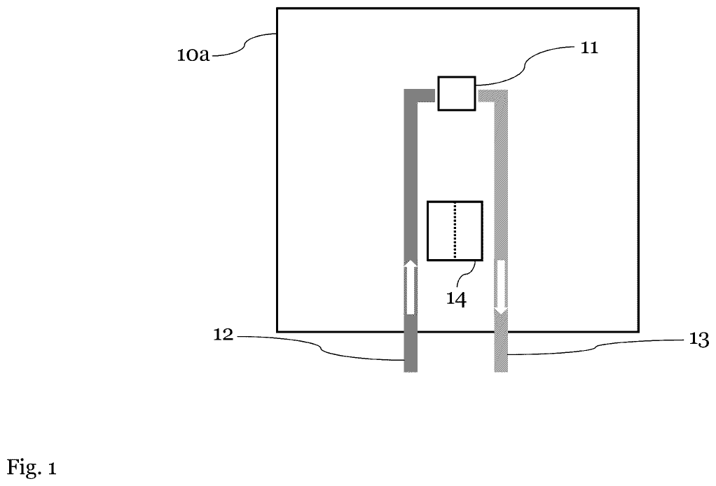

With respect to FIG. 1, an exemplary embodiment of a measurement chamber 10a for performing measurements with respect to a device under test 11, especially under different temperature conditions, is provided.

Said measurement chamber 10a comprises an inlet and/or inlet guide 12 for intake of a fluid, especially a temperature pre-conditioned fluid, into the measurement chamber 10, an outlet and/or outlet guide 13 for out-take of the fluid from the measurement chamber 10a, and a temperature conditioning element 14 arranged inside the measurement chamber 10a.

In this context, the temperature conditioning element 14 is configured to be temperature-effective with respect to the inlet and/or inlet guide 12 according to a first temperature and/or to be temperature-effective with respect to the outlet and/or outlet guide 13 according to a second temperature.

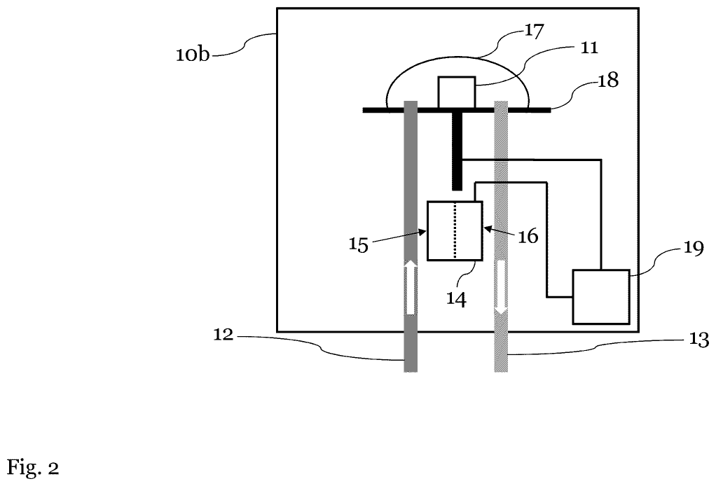

Before a further exemplary embodiment 10b of the measurement chamber based on the above-mentioned measurement chamber 10a is explained in the following in the context of FIG. 2, it is noted that for the sake of compactness, elements having already been explained above are not elucidated again but equipped with the same reference signs. It is further noted that all the explanations above regarding FIG. 1 can analogously apply for FIG. 2, and vice versa. Accordingly, especially the features of the measurement chamber 10b of FIG. 2 can partly or completely be applied to the measurement chamber 10a of FIG. 1.

With respect to the measurement chamber 10b according to FIG. 2, it is noted that it might be particularly advantageous if the measurement chamber 10b comprises or is an anechoic chamber.

Furthermore, it is to be remembered that the temperature conditioning element 14 is configured to be temperature-effective with respect to the inlet and/or inlet guide 12 according to a first temperature and/or to be temperature-effective with respect to the outlet and/or outlet guide 13 according to a second temperature. In this context, the first temperature may especially be lower than the second temperature, or vice versa.

As it can further be seen from FIG. 2, the temperature conditioning element 14 exemplarily comprises a first surface 15 of a first element temperature, and a second surface 16 of a second element temperature. In this context, the first element temperature may especially be lower than the second element temperature, or vice versa.

It is noted that for the sake of compactness, in the following, it is exemplarily assumed that the device under test 11 is measured or tested, respectively, in the context of a cooling scenario. Accordingly, the following exemplary explanations would have to be adapted analogously for a corresponding heating scenario.

With respect to the first temperature and the first element temperature, it is noted that it might be particularly advantageous if the first element temperature is lower, especially at least 5 or 10 or 15 or 20 degrees Celsius lower, than the first temperature.

With respect to the second temperature and the second element temperature, it is noted that it might be particularly advantageous if the second element temperature is higher, especially at least 5 or 10 or 15 or 20 degrees Celsius higher, than the second temperature.

Moreover, with respect to the temperature conditioning element 14, it is noted that it might be particularly advantageous if the temperature conditioning element 14 is configured such that the temperature of the fluid guided through the inlet and/or inlet guide 12 and/or through the outlet and/or outlet guide 13 is changed by at least 5 or 10 or 15 or 20 or 25 or 30 degrees Celsius after having passed the temperature conditioning element 14.

With respect to the temperature of the fluid guided through the inlet and/or inlet guide 12 and/or through the outlet and/or outlet guide 13 after having passed the temperature conditioning element 14, it is noted that said temperature may especially be understood or substantially understood as the above-mentioned first temperature or second temperature, respectively.

The foregoing term “substantially” may especially be understood as a deviation of not more than 20 percent, preferably not more than 15 percent, more preferably not more than 10 percent, most preferably not more than 5 percent, from the corresponding temperature value.

Furthermore, with respect to the above-mentioned first surface 15 and the second surface 16 of the temperature conditioning element 14, it is noted that as it can be seen from FIG. 2, the first surface is exemplarily parallel or at least substantially parallel to the second surface.

The foregoing term “substantially parallel” may especially be understood as deviation of not more than 15 degrees, preferably not more than 10 degrees, more preferably not more than 5 degrees, most preferably not more than 3 degrees, from corresponding parallelism.

Again, with respect to the temperature conditioning element 14, it is noted that the temperature conditioning element 14 may especially be plate-type. In addition to this or as an alternative, it might be particularly advantageous if the temperature conditioning element 14 comprises or is a Peltier element.

It is further noted that, as it can exemplarily be seen from FIG. 2, the inlet and/or inlet guide 12 is arranged with respect to the outlet and/or outlet guide 13 in a parallel or at least substantially parallel manner, especially at least in parts. In this context, it might be particularly advantageous if the temperature conditioning element 14 is arranged between the inlet and/or inlet guide and the outlet and/or outlet guide, especially in a region, wherein the inlet and/or inlet guide 12 is parallel or at least substantially parallel to the outlet and/or outlet guide 13.

The foregoing term “substantially parallel” may especially be understood as deviation of not more than 15 degrees, preferably not more than 10 degrees, more preferably not more than 5 degrees, most preferably not more than 3 degrees, from corresponding parallelism.

With respect to the inlet and/or inlet guide 12, it is noted that it might be particularly advantageous if the inlet and/or inlet guide 12 comprises or is at least one of an inlet hose, an inlet pipe, an inlet corrugated pipe, an inlet bellows-based hose, an inlet bellows-based pipe, or any combination thereof.

With respect to the outlet and/or outlet guide 13, it is noted that it might be particularly advantageous if the outlet and/or outlet guide 13 comprises or is at least one of an outlet hose, an outlet pipe, an outlet corrugated pipe, an outlet bellows-based hose, an outlet bellows-based pipe, or any combination thereof.

As it can further be seen from FIG. 2, the measurement chamber 10b further comprises a thermally isolated space 17 inside the measurement chamber 10b for surrounding the device under test 11. In this context, the thermally isolated space 17 exemplarily comprises a first opening for guiding the fluid from the inlet and/or inlet guide 12 into the thermally isolated space 17. Furthermore, the thermally isolated space 17 exemplarily comprises a second opening for guiding the fluid out of the thermally isolated space 17 to the outlet and/or outlet guide 13.

In this exemplary case, the thermally isolated space 17 is of ellipsoidal shape. As an alternative, the thermally isolated space 17 can be of spherical shape. Additionally or alternatively, the thermally isolated space 17 can be a thermally isolated bubble or a kind thereof.

It is noted that it might be particularly advantageous if the thermally isolated space 17 is formed by a radio frequency neutral material. In addition to this or as an alternative, it might be particularly advantageous if the thermally isolated space 17 comprises a radio frequency neutral upper dome.

It is further noted that it might be particularly advantageous if the temperature conditioning element 14 is arranged such that the temperature conditioning element 14 is as close as possible to the thermally isolated space 17 or substantially as close as possible to the thermally isolated space 17. In other words, the temperature conditioning element 14 may be arranged within the measurement chamber 10b such that the corresponding way of the fluid from the temperature conditioning element 14 to the thermally isolated space 17 is as short as possible or substantially as short as possible.

The foregoing term “substantially as close as possible” or “substantially as short as possible”, respectively, can especially be understood as not as close as possible or not as short as possible, respectively, but advantageous, exemplarily from a construction point of view, with respect to the correspondingly closest or shortest design.

With respect to the fluid, it is noted that it might be particularly advantageous if the fluid comprises or is at least one of air, nitrogen, sulfur hexafluoride, or any combination thereof. Furthermore, the fluid may comprise a certain humidity.

Again, with respect to the temperature conditioning element 14, it is noted that it might be particularly advantageous if the temperature conditioning element 14 is shielded, preferably such that the temperature conditioning element 14 does not create interference, especially electromagnetic interference, within the measurement chamber 10b.

As it can further be seen from FIG. 2, the measurement chamber 10b further comprises a positioner 18 for positioning the device under test 11, and a controller 19 for controlling the temperature conditioning element 14 and/or the positioner 18.

With respect to the positioner 18, it is noted that it might be particularly advantageous if the positioner 18 comprises at least two axis, preferably at least two rotational axis, more preferably at least three axis, most preferably three rotational axis or at least three rotational axis.

Again, with respect to the above-mentioned cooling scenario, such a cooling scenario is exemplarily described in the following.

In this context, it is assumed that the device under test 11 should be measured or tested, respectively, at a temperature of −40 degrees Celsius. In other words, a target temperature to be achieved at the device under test 11 exemplarily is −40 degrees Celsius or substantially −40 degrees Celsius. Said term “substantially” can especially be understood as a deviation of not more than 30 percent, preferably not more than 20 percent, more preferably not more than 10 percent, most preferably not more than 5 percent, from the corresponding value.

For the sake of completeness, it is noted that in the context of a heating scenario, a target temperature to be achieved at the device under test 11 may exemplarily be 85 degrees Celsius or substantially 85 degrees Celsius. Said term “substantially” can especially be understood as a deviation of not more than 30 percent, preferably not more than 20 percent, more preferably not more than 10 percent, most preferably not more than 5 percent, from the corresponding value.

Again, with respect to said cooling scenario, for instance, it is noted that the temperature of the fluid, especially the temperature pre-conditioned fluid, guided through the inlet and/or inlet guide 12 before having passed the temperature conditioning element 14 may be −40 degrees Celsius or substantially −40 degrees Celsius. It might be particularly advantageous if the temperature of the fluid, especially the temperature pre-conditioned fluid, guided through the inlet and/or inlet guide 12 before having passed the temperature conditioning element 14 is equal or substantially equal to the target temperature to be achieved at the device under test 11. Said terms “substantially” can especially be understood as a deviation of not more than 30 percent, preferably not more than 20 percent, more preferably not more than 10 percent, most preferably not more than 5 percent, from the corresponding value.

Moreover, the temperature of the fluid guided through the inlet and/or inlet guide 12 after having passed the temperature conditioning element 14 may be −55 degrees Celsius or substantially −55 degrees Celsius. It might be particularly advantageous if the temperature of the fluid guided through the inlet and/or inlet guide 12 after having passed the temperature conditioning element 14 differs from the target temperature to be achieved at the device under test 11 by at least 15 degrees Celsius or substantially at least 15 or 20 degrees Celsius. Said terms “substantially” can especially be understood as a deviation of not more than 30 percent, preferably not more than 20 percent, more preferably not more than 10 percent, most preferably not more than 5 percent, from the corresponding value.

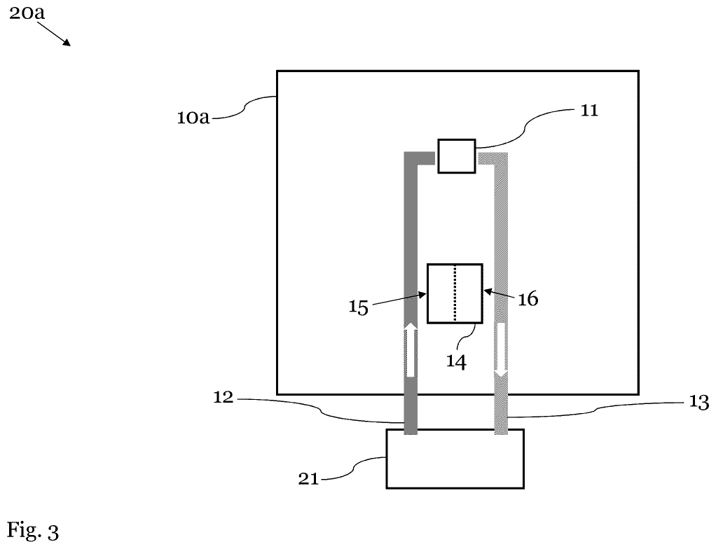

Now, with respect to FIG. 3, a system 20a comprising the above-mentioned measurement chamber 10a according to FIG. 1 and a temperature conditioning device 21 is illustrated.

In this context, the temperature conditioning device 21 is configured to condition a fluid or the above-mentioned fluid, respectively, to be fed into the inlet and/or inlet guide 12 of the measurement chamber 10a according to a first device temperature. In other words, the temperature conditioning device 21 may especially be configured to provide the above-mentioned pre-conditioned fluid.

With respect to the first device temperature, it is noted that it might be particularly advantageous if the first device temperature is equal or substantially equal to the target temperature to be achieved at the device under test 11. Said term “substantially” can especially be understood as a deviation of not more than 30 percent, preferably not more than 20 percent, more preferably not more than 10 percent, most preferably not more than 5 percent, from the corresponding value.

It is further noted that the temperature conditioning device 21 can be configured to condition the fluid taken out from the outlet and/or outlet guide 13 of the measurement chamber 10a according to a second device temperature.

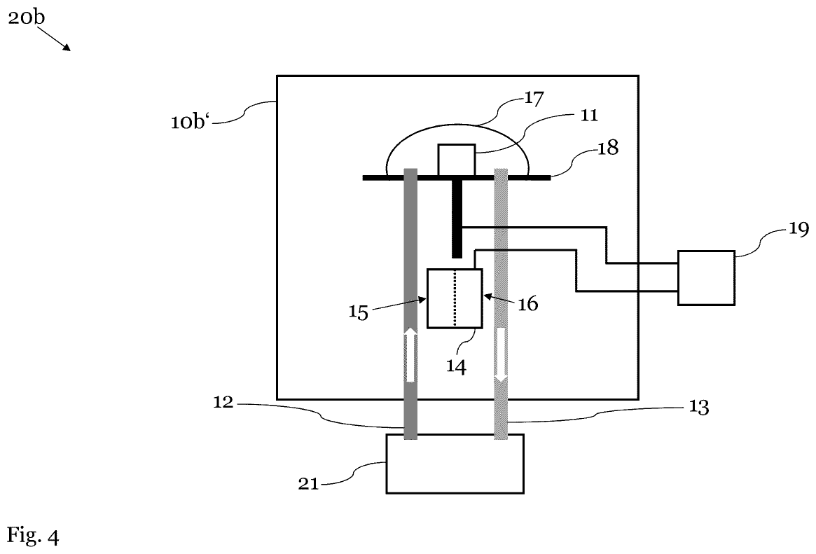

Now, with respect to FIG. 4, a system 20b comprising substantially the above-mentioned measurement chamber 10b according to FIG. 2, exemplarily equipped with reference sign 10b′ in said FIG. 4, and the temperature conditioning device 21 as explained in the context of FIG. 3 is depicted. Accordingly, the features of the system 20a, especially the temperature conditioning device 21, of FIG. 3 can partly or completely be applied to the system 20b, especially the temperature condition device 21, of FIG. 4.

As it can exemplarily be seen from FIG. 4, the measurement chamber 10b′ differs from the measurement chamber 10b according to FIG. 2 especially in that the measurement chamber 10b′ does not comprise the above-mentioned controller 19 but the system 20b does instead.

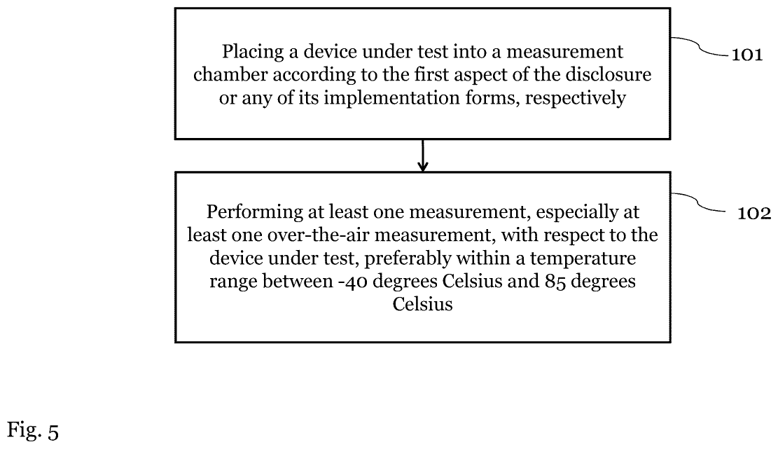

Finally, FIG. 5 illustrates a flow chart of an exemplary embodiment of a measurement method according to the third aspect of the disclosure. A first step 101 comprises placing a device under test, such as the above-mentioned device under test 11, into a measurement chamber according to the first aspect of the disclosure or any of its implementation forms, respectively, such as the above-mentioned measurement chamber 10a or 10b or 10b′. Furthermore, a second step 102 comprises performing at least one measurement, especially at least one over-the-air measurement, with respect to the device under test, preferably within a temperature range between −40 degrees Celsius and 85 degrees Celsius.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above-described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

What is claimed is:

1. A measurement chamber for performing measurements with respect to a device under test, especially under different temperature conditions, comprising:
an inlet and/or inlet guide for intake of a fluid, especially a temperature pre-conditioned fluid, into the measurement chamber,
an outlet and/or outlet guide for out-take of the fluid from the measurement chamber, and
a temperature conditioning element arranged inside the measurement chamber, wherein the temperature conditioning element is configured to be temperature-effective with respect to the inlet and/or inlet guide according to a first temperature and/or to be temperature-effective with respect to the outlet and/or outlet guide according to a second temperature.

2. The measurement chamber according to claim 1,
wherein the measurement chamber comprises or is an anechoic chamber.

3. The measurement chamber according to claim 1,
wherein the first temperature is lower than the second temperature, or
wherein the first temperature is higher than the second temperature.

4. The measurement chamber according to claim 1,
wherein the temperature conditioning element comprises a first surface of a first element temperature, and/or
wherein the temperature conditioning element comprises a second surface of a second element temperature.

5. The measurement chamber according to claim 4,
wherein the first surface is parallel or substantially parallel to the second surface.

6. The measurement chamber according to claim 1,
wherein the temperature conditioning element is plate-type, and/or
wherein the temperature conditioning element comprises or is a Peltier element.

7. The measurement chamber according to claim 1,
wherein the inlet and/or inlet guide is arranged with respect to the outlet and/or outlet guide in a parallel or substantially parallel manner.

8. The measurement chamber according to claim 7,
wherein the temperature conditioning element is arranged between the inlet and/or inlet guide and the outlet and/or outlet guide.

9. The measurement chamber according to claim 1,
wherein the inlet and/or inlet guide comprises or is at least one of an inlet hose, an inlet pipe, an inlet corrugated pipe, an inlet bellows-based hose, an inlet bellows-based pipe, or any combination thereof, and/or
wherein the outlet and/or outlet guide comprises or is at least one of an outlet hose, an outlet pipe, an outlet corrugated pipe, an outlet bellows-based hose, an outlet bellows-based pipe, or any combination thereof.

10. The measurement chamber according to claim 1, further comprising:
a thermally isolated space inside the measurement chamber for surrounding the device under test,
wherein the thermally isolated space comprises a first opening for guiding the fluid from the inlet and/or inlet guide into the thermally isolated space, and/or
wherein the thermally isolated space comprises a second opening for guiding the fluid out of the thermally isolated space to the outlet and/or outlet guide.

11. The measurement chamber according to claim 10,
wherein the thermally isolated space is of spherical or ellipsoidal shape.

12. The measurement chamber according to claim 10,
wherein the thermally isolated space is a thermally isolated bubble or a kind thereof.

13. The measurement chamber according to claim 10,
wherein the thermally isolated space is formed by a radio frequency neutral material, and/or
wherein the thermally isolated space comprises a radio frequency neutral upper dome.

14. The measurement chamber according to claim 10,
wherein the temperature conditioning element is arranged such that the temperature conditioning element is as close as possible to the thermally isolated space or substantially as close as possible to the thermally isolated space.

15. The measurement chamber according to claim 1,
wherein the fluid comprises or is at least one of air, nitrogen, sulfur hexafluoride, or any combination thereof.

16. The measurement chamber according to claim 1,
wherein the temperature conditioning element is shielded, preferably such that the temperature conditioning element does not create interference, especially electromagnetic interference, within the measurement chamber.

17. The measurement chamber according to claim 1, further comprising:
a positioner for positioning the device under test, and/or
a controller for controlling the temperature conditioning element and/or the positioner.

18. The measurement chamber according to claim 17,
wherein the positioner comprises at least two axis, preferably at least two rotational axis, more preferably at least three axis, most preferably three rotational axis or at least three rotational axis.

19. A system comprising:
a measurement chamber according to claim 1, and
a temperature conditioning device,
wherein the temperature conditioning device is configured to condition a fluid to be fed into the inlet and/or inlet guide of the measurement chamber according to a first device temperature, and/or wherein the temperature conditioning device is configured to condition the fluid taken out from the outlet and/or outlet guide of the measurement chamber according to a second device temperature.

20. A measurement method comprising the steps of:
placing a device under test into a measurement chamber according to claim 1, and
performing at least one measurement, especially at least one over-the-air measurement, with respect to the device under test, preferably within a temperature range between −40 degrees Celsius and 85 degrees Celsius.
